(19) United States
(12) Patent Application Publication
(10) Pub. No.: US 2026/0243730 A1
(43) Pub. Date: Aug. 20, 2026

(54) Determining an Aging State of a Contacting Layer of a Semiconductor Component and Semiconductor Assembly

(71) Applicant: Siemens Aktiengesellschaft, München (DE)

(72) Inventors: Gerhard Mitic, München (DE); Stefan Stegmeier, München (DE); Kai Kriegel, München (DE); Heinz Dietrich Philipp Bickel, München (DE)

(73) Assignee: Siemens Aktiengesellschaft, München (DE)

(21) Appl. No.: 19/159,424

(22) PCT Filed: Feb. 14, 2024
(86) PCT No.: PCT/EP2024/053675

§ 371 Date: Aug. 25, 2025

(30) Foreign Application Priority Data
Feb. 28, 2023 (EP) 23159099.3

(51) Int. Cl. G01N 29/04; G01N 27/20; G01N 27/24; G01N 29/24

(52) U.S. Cl. CPC G01N 29/041; G01N 27/20; G01N 27/24; G01N 29/2437; G01N 2291/0231; G01N 2291/102

(57) ABSTRACT

Various embodiments of the teachings herein include a semiconductor assembly. An example includes: a semiconductor component with a first side connected to a carrier layer by a first contacting layer; a second contacting layer on a second side of the semiconductor component facing away from the first contacting layer; an emitter and a sensor arranged on the semiconductor assembly, wherein, when the semiconductor assembly is in an operational state, the emitter influences a surface of the second contacting layer detected by the sensor; and evaluation electronics in communication with the sensor to evaluate sensor data and ascertain a surface quality characteristic value of the surface.

### CROSS-REFERENCE TO RELATED APPLICATIONS

This application is a U.S. National Stage Application of International Application No. PCT/EP2024/053675 filed Feb. 14, 2024, which designates the United States of America, and claims priority to EP Application No. 23159099.3 filed Feb. 28, 2023, the contents of which are hereby incorporated by reference in their entirety.

### TECHNICAL FIELD

The present disclosure relates to semiconductors. Various embodiments of the teachings herein include systems and/or methods for determining an aging state of a contacting layer for securing a semiconductor component in a semiconductor assembly, the aging state of a bonding wire connection in a semiconductor assembly, and semiconductor assemblies.

### BACKGROUND

In semiconductor assemblies, in particular for power electronics, various semiconductor components, such as, for example, IGBTs, MOSFETS or diodes are installed on substrates or printed circuit boards. Herein, a contacting layer, which may also include a solder layer, for example, is generally provided for contacting the semiconductor components. However, in power electronics components are exposed to a very high thermomechanical stress during operation. This means that power electronics components are at greater risk of accidental failure due to aging conditions and therefore there is constant need to estimate the aging state of a respective assembly.

For this purpose, in the prior art, electrical measured variables such as, for example, the gate-emitter voltage or the inrush current are measured. Changing thermal resistances due to possible delamination or cracks in a contacting layer can be used to draw conclusions regarding specific aging behavior. However, these measurements are generally very complex because they require high measurement accuracy and high temporal resolution. These cannot generally be performed during operation of the semiconductor component. Instead, laboratory conditions are required to perform the complex and accurate measurements mentioned above. Furthermore, during the operation of a power electronics component, for example in an electric vehicle, it is not possible under real conditions to remove the component or assembly and examine the corresponding solder joints or contacting layers under a microscope. Furthermore, the aging state can be estimated by evaluating temperature-sensitive parameters and temperature cycles determined in service life tests. However, the measurement of these temperature-sensitive parameters is likewise very complex.

### SUMMARY

The teachings of the present disclosure include systems and/or methods for determining an aging state of a contacting layer of a semiconductor component in a semiconductor assembly and a semiconductor assembly, wherein the aging state is determined during operation or at least in the operational state of the component or the semiconductor assembly.

For example, some embodiments include a method for determining an aging state of a contacting layer for securing a semiconductor component (2) in a semiconductor assembly (4) comprising: applying a first contacting layer (6) to a carrier layer (8), for securing the semiconductor component (2) to this carrier layer (8), wherein a second contacting layer (12) is applied to the semiconductor component (2) on the side (10) facing away from the first contacting layer (6), attaching an emitter (14) and a sensor (16) to the semiconductor assembly (4) which serve to determine a surface quality of a surface (13) of the second contacting layer (12), connecting the sensor (16) to evaluation electronics (18) for captured sensor data, putting the semiconductor assembly (4) into an operational state and operating the semiconductor assembly (4) and evaluating the sensor data by means of the evaluation electronics (18) in the operational state of the semiconductor assembly (4) for the purpose of ascertaining a surface quality characteristic value of the second contacting layer (12).

In some embodiments, a tolerance range (26) for the surface quality characteristic value (28) is stored in a database (24) and information (34) is sent out by the evaluation electronics (18) if an ascertained surface quality characteristic value (28) lies outside the tolerance range (26).

In some embodiments, a correlation function (30) between the surface quality characteristic value (28) of the second contacting layer (12) and an aging characteristic value (36) of the first contacting layer (6) is stored in the database (24).

In some embodiments, the information (34) is sent out when the aging characteristic value (36) ascertained by the correlation function (30) lies outside the tolerance range (26).

In some embodiments, the sensor (16) is attached on or at the surface (13) of the second contacting layer (12).

In some embodiments, electromagnetic or mechanical waves which are influenced by the surface (13) of the second contacting layer (12) are captured by means of the sensor (16).

In some embodiments, the emitter (14) for generating electromagnetic waves is directed toward the surface (13) and the sensor (16) detects the waves reflected from the surface (13) and forwards them as sensor data to the evaluation electronics (18).

In some embodiments, the emitter (14) for generating mechanical waves is directed toward the surface (13) and the sensor detects the waves reflected from the surface (13) and forwards them as sensor data to the evaluation electronics (18).

In some embodiments, the mechanical waves are emitted by means of a piezoelectric actuator (38) or a MEMS actuator (40).

In some embodiments, the sensor (16) is a sound sensor.

In some embodiments, a capacitive or resistive value is measured as sensor data by means of the sensor (16) at the second contacting layer (12).

As another example, some embodiments include a semiconductor assembly with a semiconductor component (2), wherein the semiconductor component (2) is connected to a carrier layer (8) by means of a first contacting layer (6) and the semiconductor component (2) has a second contacting layer (12) on a side (10) facing away from the first contacting layer (6), characterized in that an emitter (14) and a sensor (16) are arranged on the semiconductor assembly (4) such that, when the semiconductor assembly is in an operational state, the emitter (14) influences a surface (13) of the second contacting layer (12) which can be detected by the sensor (16), wherein the sensor (16) is connected to evaluation electronics (18) for evaluating sensor data for the purpose of ascertaining a surface quality characteristic value (28) of the surface (13).

In some embodiments, the emitter (14) and sensor (16) are suitable for emitting and detecting electromagnetic waves or mechanical waves.

In some embodiments, the sensor (16) is suitable for detecting resistive or capacitive signals.

In some embodiments, the emitter (14) and/or sensor (16) are placed directly or with a spacing of at most 5 mm on the second contacting layer (12).

### BRIEF DESCRIPTION OF THE DRAWINGS

Advantageous embodiments and further features of the teachings herein are described in more detail with reference to the following figures. Herein, features with the same designation but in different embodiments are in each case given the same reference symbol. Herein, the figures show:

FIG. 1 a schematic cross section through a semiconductor assembly with a semiconductor component and sensor for determining an aging state incorporating teachings of the present disclosure;

FIG. 2 an enlarged representation of a contacting layer with protruding hillocks;

FIG. 3 a schematic representation of the transmission of sensor data to evaluation electronics incorporating teachings of the present disclosure;

FIG. 4 a schematic representation of a semiconductor component with a contacting layer and its surface with combinations of sensors and emitters arranged thereon incorporating teachings of the present disclosure; and

FIG. 5 a comparable representation to that in FIG. 4 in an alternative embodiment incorporating teachings of the present disclosure.

### DETAILED DESCRIPTION

As an example, some embodiments of the teachings herein include a method for determining an aging state of a contacting layer for securing a semiconductor component in a semiconductor assembly, wherein the method comprises:
applying a first contacting layer to a carrier layer for securing the semiconductor component to this carrier layer,
wherein a second contacting layer is applied to the semiconductor component on the side facing away from the first contacting layer, attaching a emitter and a sensor to the semiconductor assembly, which serve to determine a surface quality of a surface of the second contacting layer,
connecting the sensor to evaluation electronics for captured sensor data,
putting the semiconductor assembly into an operational state and operating the semiconductor assembly, and
evaluating data by means of the evaluation electronics in the operational state of the semiconductor assembly for the purpose of ascertaining a surface quality characteristic value of the second contacting layer.

A contacting layer is a layer that serves to establish electrical contact. Herein, this generally entails a metallic layer with appropriate electrical conductivity. In principle, this should also be understood to mean a solder layer, but it can also be a metallic foil within this solder layer or separate therefrom. A solder drop which serves to secure a bonding wire can also be referred to as a contacting layer.

As mentioned in the introduction, a semiconductor component is, for example, an IGBT, a transistor or a diode. In this context, reference is made in particular to power electronics components. However, the method described is also readily applicable to other semiconductor components. A semiconductor assembly is an assembly in which at least one semiconductor component is mounted on a substrate and corresponding contacts are provided.

Herein, the first contacting layer is a contact between the semiconductor component and a carrier layer. Herein, the carrier layer is generally also again an electrically conductive layer, such as, for example, a copper layer or a copper plate. However, depending upon the composition of the semiconductor assembly, the carrier layer can also be a non-conductive layer or plate, such as, for example, a ceramic substrate. Herein, the semiconductor component is contacted with this carrier layer via the first contacting layer, SO that the semiconductor component substantially covers the first contacting layer, so that it is virtually impossible to determine the aging of this contacting layer, at least not directly. A second contacting layer of the semiconductor component is applied on a side of the semiconductor component facing away from the first contacting layer and the carrier layer, i.e. on the opposite side. This second contacting layer is generally connected to a contact wire for contacting.

In the example method, an emitter and a sensor are attached to the semiconductor assembly and serve to determine a surface quality of a surface of the second contacting layer. Herein, the emitter and sensor can preferably be accommodated in an integrated component. In the case of the measurement of waves, such as electromagnetic waves, the emitter is, for example, a diode, a laser or another component emitting electromagnetic waves. The sensor is in turn in particular suitable for detecting waves reflected from the surface such as electromagnetic waves, for example, but also mechanical waves, such as sound waves. By emitting and reflecting waves, changes in the surface quality of the surface of the second contacting layer can be determined. This requires evaluation electronics that are connected to the sensor and evaluate the sensor data, i.e. information about the reflected waves. Emitters as emitters for waves are merely an example, and emitters can also be understood in the broader sense to be the application of an electric current or an electric potential to the surface by means of an electrode, wherein herein the sensor is in turn a measuring unit which measures an electric resistance and a capacitance. The surface of the second contacting layer can also be a bonding wire which is attached to the second contacting layer. Its surface can also be advantageously observed with regard to aging.

Herein, the term operational state or operation of the semiconductor assembly should be understood as meaning that both the emitter and the sensor are installed in the semiconductor assembly in such a way that the surface quality can be measured and evaluated during operation of the semiconductor assembly or at least in an installed state in an operational state, i.e. in situ.

Herein, the term surface quality means that the surface of the second contacting layer changes during operation in particular due to thermomechanical loads. For example, herein, there is a protrusion of so-called hillocks or needle-shaped tips. However, these protruding hillocks on the surface also mean a depletion of material at other points in the second contacting layer. Such hillocks or general surface changes are quite common during the operation of contacting layers and are acceptable to a certain extent. However, the number of such surface changes indicates the aging state of the contacting layer, and it can be determined empirically which acceptable aging state of the semiconductor assembly correlates with which surface condition. In this way, a surface condition characteristic value can be determined from the captured sensor data by the evaluation electronics in the operational state of the semiconductor assembly.

In contrast to the prior art, the example method described is suitable for determining usable information about the state of aging of a semiconductor assembly during the operation of this assembly, thus enabling this assembly to be replaced in good time before a failure occurs, if necessary. To ascertain this aging state, a tolerance range for the surface quality characteristic value may be stored in a database and information is sent out by the evaluation electronics if an ascertained surface quality characteristic value lies outside this tolerance range. This information can, for example, be sent to control electronics, which, in turn, display information on a unit indicating that the assembly needs to be replaced.

Furthermore, it has been found that there is a correlation between the aging state of the first contacting layers; the contacting layer that cannot be observed by the sensor because it is obscured by the semiconductor component, and the second contacting layer or the surface quality. This means that in practice there is a correlation between, for example, the number of hillocks per unit area and the number of microcracks in the first contacting layer. This correlation is in turn determined empirically, from which a correlation function can be derived. Hence, an aging characteristic value of the first contacting layer can be ascertained from the surface quality characteristic value of the second contacting layer, wherein the corresponding correlation function is likewise stored in the database. Herein, it should be noted that both the evaluation electronics and the database can be combined on an integrated circuit, which in turn can be an integral component of the semiconductor assembly. In this way, the method described enables conclusions to be drawn not only about the aging of the second contacting layer, but also about the aging of the first contacting layer, which is obscured per se.

In some embodiments, the information is sent out by the evaluation electronics when the aging characteristic value ascertained by the correlation function lies outside the tolerance range.

In some embodiments, the sensor is attached on or at the surface of the second contacting layer. In some embodiments, the sensor is embodied in an integral component with the emitter. This component can be easily applied to the surface of the second contacting layer so it is firmly attached to the surface and always provides reliable measurement data. Herein, as already mentioned, the emitters can either be emitters of electromagnetic waves, but also of sound waves. Piezoelectric actuators or MEMS actuators are particularly suitable for emitting sound waves. Corresponding sensors interacting therewith are suitable for detecting these sound waves or mechanical waves.

Some embodiments include a semiconductor assembly having at least one semiconductor component, wherein the semiconductor component is connected to a carrier layer by means of a first contacting layer and the semiconductor component has a second contacting layer on a side facing away from the first contacting layer. An emitter and a sensor are attached to the semiconductor assembly in such a way that, when the semiconductor assembly is in an operational state, the emitter influences a surface of the second contacting layer in a manner that can be detected by the sensor. Herein, the sensor is connected to evaluation electronics for evaluating the sensor data and determining a surface quality parameter of the surface.

The described semiconductor assembly has similar features to the method as device features, wherein the terms used are defined identically. The semiconductor assembly also has the same advantages which have already been explained with respect to the method. These are in particular the possibility of checking the semiconductor assembly during operation for aging phenomena of contacting layers and indicating premature removal of the semiconductor assembly. In this semiconductor assembly as well, it is expedient that electromagnetic or mechanical waves are emitted by means of the emitter and detected by means of the sensor. As an alternative to wave emission, it is also expedient for the emitter to be embodied in such a way that a resistive or capacitive signal is detected by the sensor.

The direct attachment of the emitter and/or the sensor or an integrated component containing the emitter and sensor to the second contacting layer or at least with a small spacing is expedient for fault-free measurement during operation or in the operational state of the semiconductor assembly.

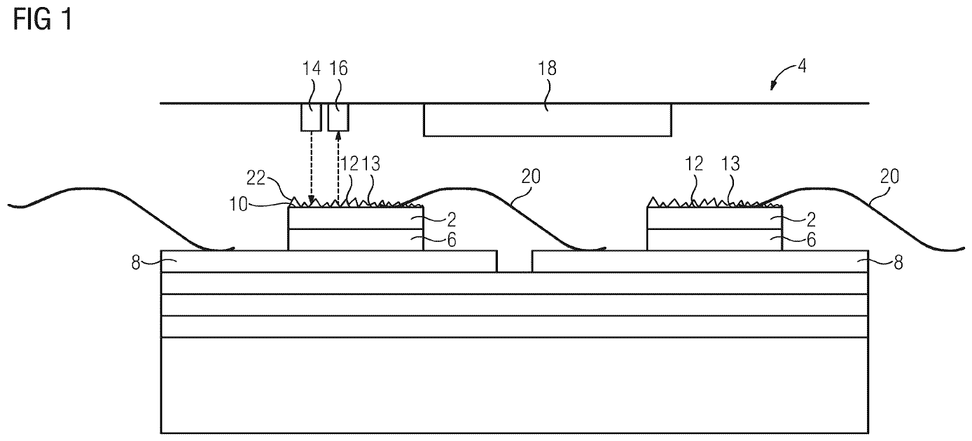

FIG. 1 shows a section of a semiconductor assembly 4, which may comprise a plurality of layers, substrates and base plates, not specified in any more detail here, wherein a plurality of such sections arranged one on top of the other can form the entire semiconductor assembly 4. The description here is initially directed toward a carrier layer 8, which is generally an electrically conductive layer, such as, for example, a copper plate. Applied to this is a first contacting layer 6, for example in the form of a solder layer on which semiconductor component, for example an IGBT, is soldered. Here, this semiconductor component 2 in turn has a second contacting layer 12 on a side 10 facing away from first contacting layer 6, the surface 13 of which is observed by means of an emitter 14 and a sensor 16.

A contact wire 20 is in turn electrically conductively contacted on this second contacting layer 12. The surface 13 of the second contacting layer 12 is shown greatly exaggerated in FIG. 1, wherein here peaks, known in technical terminology as hillocks, are shown here. These hillocks arise due to thermomechanical loads during operation of the semiconductor assembly 4.

In the example shown in FIG. 1, the emitter 14 is embodied in the form of a diode for emitting electromagnetic waves with a specific wavelength. Here, the sensor 16 is a sensor for detecting electromagnetic waves in the emitted wavelength or in its order of magnitude. Here, the combination of the emitter 14 and sensor 16 is arranged just above the second contacting layer 12 in a direct viewing line thereto. The distance between the emitter 14, sensor 16 and the surface 13 is shown greatly exaggerated in FIG. 1. Herein, these two components are arranged as close as possible to the surface 13, e.g. directly on the surface 13, as will be described with reference to the further figures. However, in the example shown here there is a distance of approximately 2 mm, preferably less than 5 mm, wherein the emitter 14 and sensor 16 are arranged on a further plate, not specified in more detail here, above the semiconductor component 2.

Furthermore, evaluation electronics 18 in the form of an integrated circuit with a database likewise integrated therein are arranged on this plate, which is likewise not named. The sensor 16 is in direct contact with these evaluation electronics 18 and transmits measured sensor data thereto. As shown schematically in FIG. 3, the evaluation electronics 18, in interaction with the database 24, in turn calculate a surface quality characteristic value 28. A tolerance band or tolerance range 26 (see FIG. 3) is provided for this characteristic value 28.

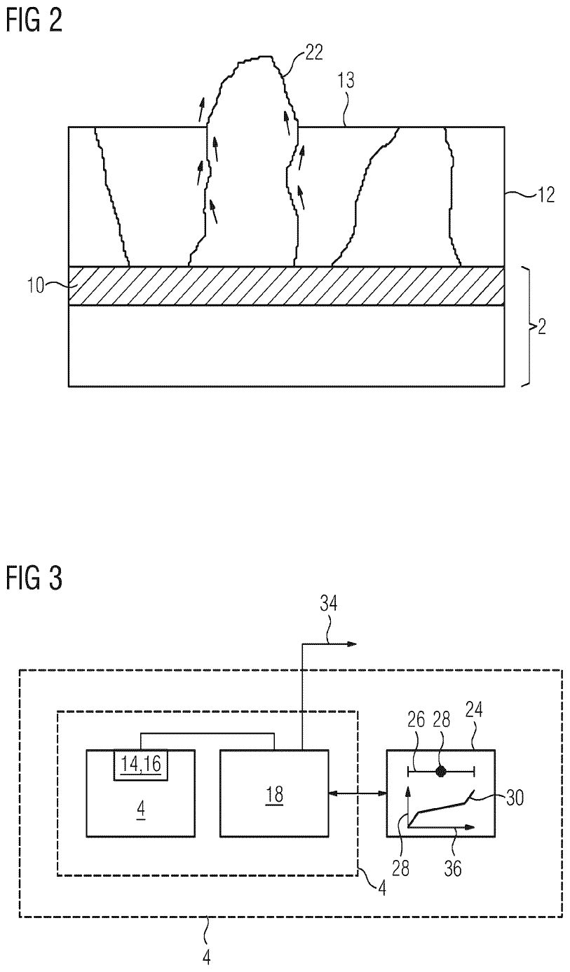

The surface quality characteristic value 28 is determined on the basis of a number per unit area or an average height of hillocks 22. To this end, empirical data recorded, for example, microscopically in the laboratory is available. In this case, it is ascertained which number or which height per unit area of hillocks 22 are still available for reliable contact and for a reliable mode of operation of the second contacting layer 12. One example of a hillock is depicted in FIG. 2 in a greatly enlarged and highly schematic form. In addition to the surface quality characteristic value 28 ascertained, this tolerance range 26 is also defined from these empirical values. These values 26 and 28 are stored in the database 24. If a surface quality characteristic value 28 that lies outside the tolerance range 26 is ascertained by means of the evaluation electronics 18 on the basis of the transmitted sensor data, the evaluation electronics 18 emits a signal 34 that is, for example, transmitted to further electronics, not shown here, for further processing. These further electronics can then in turn indicate on a display, likewise not shown here, that the semiconductor assembly 4 has to be replaced in a specific period of time. For example, in the case of an electric vehicle, information about the aging state of the contacts in the semiconductor assembly, in particular a power semiconductor assembly can be stored in the on-board electronics and read out during a maintenance interval.

The dashed boxes around the individual assemblies 4, 18 and 24 i.e. the semiconductor assembly 4, the evaluation electronics 18 and the database 24 in each case are intended to illustrate that these respective assemblies can be highly integrated or completely separate. In some embodiments, the evaluation electronics 18 are integrated within the semiconductor assembly; however, the semiconductor assembly can also use evaluation electronics 18 that are spatially separated therefrom to evaluate the sensor data. The database 24 can also be integrated directly in the semiconductor assembly 4; however, it can also be located on a separate component, possibly even in a cloud.

In some embodiments, an empirical relationship between the first contacting layer 6 and the second contacting layer 12 can also be stored in the database 24. This is particularly advantageous because the semiconductor component 2 obscures a direct view of sensor 16 of the first contacting layer 6. Here, once again, empirical measurements can be taken under laboratory conditions to determine which surface quality of the second contacting layer 12 correlates with which aging state of the first contacting layer 6 in practice. This can be used to ascertain a correlation function 30 defining a correlation between the surface quality characteristic value 28 of the second contacting layer 12 and an aging characteristic value 26 of the first contacting layer 6. This correlation 30 can also define the tolerance range 26 for the characteristic value 28 so that a signal 34 is produced by the evaluation electronics 18 when the aging characteristic value 36 has exceeded a critical value which correlates with a specific characteristic value 28. Thus, aging of the first contacting layer 6, for example due to microcracks, can also be reliably predicted during operation of the semiconductor assembly 4 and corresponding measures can be initiated.

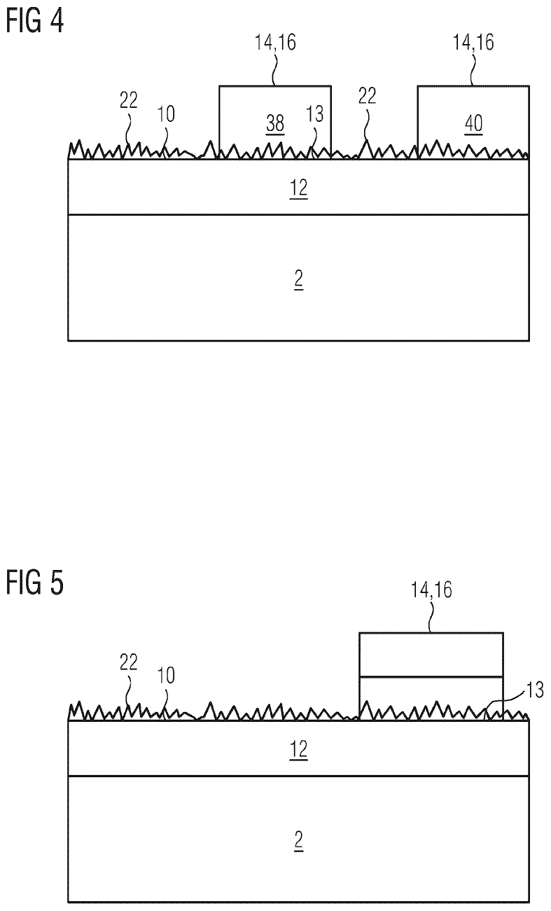

FIG. 1 depicts a pairing of the emitter 14 and sensor 16 arranged at a slight distance from the surface 13 of the layer 12. As already mentioned, this combination may be integrated into a single component and can also be arranged directly on the surface 13 of the second contacting layer 12. This is depicted in FIG. 4 and FIG. 5. However, further alternatives to the electromagnetic waves emitted by the emitter 14 in FIG. 1 are described here. For example, in addition to the electromagnetic waves from the emitter 14, mechanical waves, for example in the form of sound waves, can also be emitted. For this purpose, the emitter 14 can be embodied in the form of a piezoelectric actuator or in the form of a MEMS actuator. Both actuators serve as emitters 14 of sound waves, which are reflected on the surface 13 of the contacting layer 12 and recorded by a corresponding sound sensor 16. Herein, the information in the form of sensor data is in turn relayed to the evaluation electronics 18, in the same way as shown in FIG. 1 and FIG. 3.

FIG. 5 shows an embodiment similar to that in FIG. 4; however, here an electrode with an intermediate dielectric is applied to the surface 13 as the sensor 16-emitter 14 combination and a capacitance is measured which is changed by the surface 13 and its quality. If a plurality of hillocks 22 are present, the capacitance between the dielectric and the electrode, which is relayed as sensor data to the evaluation electronics 18, is changed. Likewise, in the comparable construction, it is expedient to measure the resistance at the surface 13 rather than the capacitance; this is likewise characteristically influenced by the number of hillocks 22. In this embodiment, the electrode at which a corresponding voltage or charge is applied is regarded as the emitter 14, and the corresponding capacitance or resistance is measured by a measuring unit, not shown in further detail here, as the sensor 16.

### LIST OF REFERENCE SYMBOLS

2 Semiconductor component
4 Semiconductor assembly
6 First contacting layer
8 Carrier layer
10 Side facing away
12 Second contacting layer
13 Surface
14 Emitter
16 Sensor
18 Evaluation electronics
20 Contact wire
22 Hillocks
24 Database
26 Tolerance range
28 Surface quality characteristic value
30 Correlation function
32 Dielectric, resistance
34 Information
36 Aging characteristic value
38 Piezoelectric actuator
40 MEMS actuator

What is claimed is:

1. A method for determining an aging state of a contacting layer for securing a semiconductor component in a semiconductor assembly, the method comprising:
applying a first contacting layer to a carrier layer to secure a first side of the semiconductor component to the carrier layer;
wherein a second contacting layer is disposed on a second side of the semiconductor component facing away from the first side;
attaching an emitter and a sensor to the semiconductor assembly to determine a surface quality of a surface of the second contacting layer;
connecting the sensor to evaluation electronics for captured sensor data;
putting the semiconductor assembly into an operational state and operating the semiconductor assembly; and
evaluating the sensor data refusing the evaluation electronics in the operational state to ascertain a surface quality characteristic value of the second contacting layer.

2. The method as claimed in claim 1, further comprising:
storing a tolerance range for the surface quality characteristic value in a database; and
sending information out from the evaluation electronics if an ascertained surface quality characteristic value lies outside the tolerance range.

3. The method as claimed in claim 2, further comprising storing a correlation function between the surface quality characteristic value of the second contacting layer and an aging characteristic value of the first contacting layer in the database.

4. The method as claimed in claim 3, wherein the information is sent out when the aging characteristic value ascertained by the correlation function lies outside the tolerance range.

5. A method as claimed in claim 1, wherein the sensor is attached on or at the surface of the second contacting layer.

6. A method as claimed in claim 1, further comprising capturing electromagnetic or mechanical waves influenced by the surface of the second contacting layer using the sensor.

7. The method as claimed in claim 6,
the emitter is directed toward the surface; and
the sensor detects waves reflected from the surface and forwards them as sensor data to the evaluation electronics.

8. The method as claimed in claim 6, wherein;
the emitter for generating mechanical waves is directed toward the surface; and
the sensor detects the waves reflected from the surface and forwards them as sensor data to the evaluation electronics.

9. The method as claimed in claim 8, wherein the mechanical waves are emitted from a piezoelectric actuator or a MEMS actuator.

10. The method as claimed in claim 9, wherein the sensor comprises a sound sensor.

11. The method as claimed in claim 1, wherein the sensor measures a capacitive or resistive value at the second contacting layer.

12. A semiconductor assembly comprising:
a semiconductor component with a first side connected to a carrier layer by a first contacting layer;
a second contacting Layer on second side of the semiconductor component facing away from the first contacting layer;
an emitter and a sensor arranged on the semiconductor assembly, wherein, when the semiconductor assembly is in an operational state, the emitter influences a surface of the second contacting layer detected by the sensor; and
evaluation electronics in communication with the sensor to evaluate sensor data and ascertain a surface quality characteristic value of the surface.

13. The semiconductor assembly as claimed in claim 12, wherein the emitter produces electromagnetic waves or mechanical waves.

14. A semiconductor assembly as claimed in claim 12, wherein the sensor detects resistive or capacitive signals.

15. The semiconductor assembly as claimed in claim 12, wherein the emitter and/or sensor are placed directly or with a spacing of at most 5 mm on the second contacting layer.
